(19) United States
(12) Patent Application Publication
(10) Pub. No.: US 2008/0013283 A1
(43) Pub. Date: Jan. 17, 2008

(54) Mechanism for cooling electronic components

(76) Inventors: Gary L. Gilbert, San Diego, CA (US); Guoping Xu, San Diego, CA (US); Nicholas E. Aneshansley, San Diego, CA (US); Edward Lee Follmer, Del Mar, CA (US)

Correspondence Address: HICKMAN PALERMO TRUONG & BECKER, LLP;AND SUN MICROSYSTEMS, INC., 2055 GATEWAY PLACE, SUITE 550, SAN JOSE, CA, 95110-1089, US

(21) Appl. No.: 11/488,281

(22) Filed: Jul. 17, 2006

(51) Int. Cl. H05K 7/20

(52) U.S. Cl. 361/715

(57) ABSTRACT

A mechanism is disclosed for cooling electronic components of a module housed in a chassis. The chassis may be, for example, a rack or other housing, which may contain many such modules. The system comprises an external cooling system, and an internal cooling system for cooling electronic components on the module. The internal cooling system may reside on the module. The internal cooling system can be removed from the chassis to enable servicing components on the module without disconnecting any lines carrying cooling fluid in either fluid cooling system.

### BACKGROUND

Modern electronic components, such as computer processing units, generate a tremendous amount of heat, which must be removed from the electronic components. One technique to remove the heat is to mount a mechanical heat sink to the electronic component to transfer heat to the heat sink and then force air over the heat sink to dissipate the heat.

A drawback with heat sinks is that the amount of heat that can be removed is limited by the size of the heat sink that can be used, as well as the volume of air flow that is practical to deliver. The size of heat sinks is limited by the desire to house the electronics in a reasonably sized chassis. Moreover, air is a relatively poor heat exchanger.

A trend in electronics is for each generation of at least some electronic components, such as CPUs, to generate more heat than previous generations. Thus, there is an increasing need for more efficient heat exchange systems. Furthermore, modern data centers comprise many racks of computer systems, each rack generating tremendous heat. Thus, air cooling of electronics may not be adequate.

Another technique for cooling electronic components involves using a liquid heat exchanger. One type of liquid heat exchanger provides some means to have a liquid flow in close proximity to the electronic component such that the liquid is thermally coupled with the electronic component to transfer heat from the electronic component to the liquid.

Integrated liquid-to-liquid heat exchangers have also been used to exchange heat from a first liquid to a second liquid via one or more plate surfaces between the liquids without the liquids mixing. This type of device has inlets and outlets that allow the liquids to enter and leave the heat exchanger. Typically, some sort of a clamp or valve is used to couple a pipe carrying each liquid to the device.

If an integrated liquid-to-liquid heat exchanger is used to provide cooling for an electronic device, problems arise when servicing the electronic device. In some system, an integrated liquid-to-liquid heat exchanger is connected to a rack that houses the electronic components. To service the electronic components, at least one of the pipes carrying the cooling liquids must be disconnected from the heat exchanger to allow access to the electronic components. For example, one or more fluid lines may need to be disconnected to remove a module, which holds electronic components, from the rack. The liquid lines can be coupled to the heat exchanger with a device known as a fluid coupling, which allows the coolant line to be temporality disconnected without substantial fluid leakage. Thus, the electronic components can be serviced by temporarily disconnecting the fluid couplings.

However, there are several problems with fluid couplings. A first problem is that fluid couplings typically only allow a limited amount of fluid flow, which restricts cooling ability. Another problem is that fluid couplings are prone to leak, which could cause substantial damage to electronic components. Still another problem is that fluid couplings are expensive.

Because of these and potentially other drawbacks, these approaches do not provide wholly satisfactory results. Consequently, an improved mechanism for cooling electronic components is needed.

### SUMMARY

In accordance with one embodiment of the present invention, there is provided a system for cooling electronic components of a module (e.g., a motherboard) housed in a chassis. The chassis may be, for example, a rack or other housing, which may contain many such modules. The system comprises an external cooling system, and an internal cooling system for cooling electronic components on the module. The internal cooling system may reside on the module. The internal cooling system can be removed from the chassis to enable servicing of components on the module without disconnecting any lines carrying cooling fluid in either cooling system. For example, a module on which the internal cooling system resides can be removed from the chassis (e.g., rack) without disconnecting any coolant carrying lines.

The external cooling system has a cold plate that is coupled to the chassis. The cold plate is coupled to one or more external lines that carry a first cooling fluid. The first fluid is thus thermally coupled to the cold plate. The internal cooling system comprises a heat rejecter plate coupled to an internal line that carries a second cooling fluid to allow fluid in the internal line to be thermally coupled to the heat rejecter plate. The internal line is thermally coupled to one or more electronic components. Therefore, the internal line allows heat to be transferred from the one or more electronic components to the heat rejecter plate.

When the internal cooling system is in the chassis, the heat rejecter plate is thermally coupled to the cold plate to transfer heat from the internal cooling system to the external cooling system. As previously mentioned, the internal cooling system can be removed from the chassis to enable servicing of electronic components without disconnecting any lines carrying cooling fluid in either cooling system. For example, the external line is kept coupled to the cold plate and the internal line is kept coupled to the heat rejecter plate when the internal cooling system is removed from the chassis. The electronic components that are serviced can be those that are cooled by the internal cooling system or other electronic components on the module.

In one embodiment, the internal cooling system comprises an active liquid cooling loop. In another embodiment, the internal cooling system comprises a passive phase change loop.

In accordance with one embodiment of the present invention, there is provided a method of servicing electronic components on a module that is housed in a chassis. A cold plate is coupled to the chassis. The cold plate is part of a cooling system that is external to the chassis and is coupled to an external line that carries a first cooling fluid. The module comprises an internal cooling system for cooling at least one of the electronic components on the module. The internal cooling system comprises a heat rejecter plate and an internal line that carries a second fluid. The heat rejecter plate is thermally coupled to the internal line. The cold plate is thermally coupled to the heat rejecter plate to transfer heat from the internal cooling system to the external cooling system.

The method comprises the following steps. The internal cooling system is removed from the chassis, to thermally de-coupling the heat rejection plate from the cold plate, without de-coupling the internal line from the heat rejection plate and without de-coupling the external line from the cold plate. One or more of the electronic components are serviced with the internal cooling system removed from the chassis. The internal cooling system is placed back into the chassis, to thermally couple the heat rejection plate to the cold plate.

Another embodiment in accordance with the present invention is a module housing electronic components. The module comprises a cooling system for cooling at least one of the electronic components of the module. The cooling system comprises a heat rejecter plate and a line coupled thereto that carries a cooling fluid. The line is thermally coupled to the electronic component. The module has a mechanism having a first position that allows the module to be freely moved within a chassis to insert and remove the module from the chassis. The mechanism has a second position that causes the heat rejecter plate to be thermally coupled to a cold plate residing in the chassis to transfer heat from the cooling system to an external cooling system that comprises the cold plate. Thus, the mechanism allows the module to be removed from the chassis, to thermally de-coupling the heat rejecter plate from the cold plate, without de-coupling the line from the heat rejecter plate.

Notice that servicing electronic components in the above manner does not require any fluid couplings to be broken. Thus, the likelihood of cooling fluid leaking either during the servicing or at another time is substantially reduced compared to techniques that disconnect fluid couplings. Moreover, cooling electronic components in the above manner is very effective in that heat is transferred from one fluid cooling system to another. Furthermore, servicing electronic components in the above manner is cost effective. For example, expensive fluid couplings are not used.

### BRIEF DESCRIPTION OF THE DRAWINGS

FIG. 1 shows a system for cooling electronic components in accordance with an embodiment of the present invention.

FIG. 2 shows a module that can be removed from a chassis without disconnecting any cooling fluid carrying lines, in accordance with an embodiment of the present invention.

FIG. 3 shows steps of a process of servicing electronic components in accordance with one embodiment of the present invention.

FIG. 4A shows a cross sectional view of a cooling system having a passive phase change loop, in accordance with an embodiment of the present invention, taken along line A-A′ of FIG. 4B.

FIG. 4B shows a cross sectional view of the system of FIG. 4A, in accordance with an embodiment of the present invention, taken along line B-B′ of FIG. 4A.

FIG. 4C shows a cooling system having an active liquid cooling pump in accordance with one embodiment of the present invention.

### DETAILED DESCRIPTION OF EMBODIMENT(S)

### System Overview

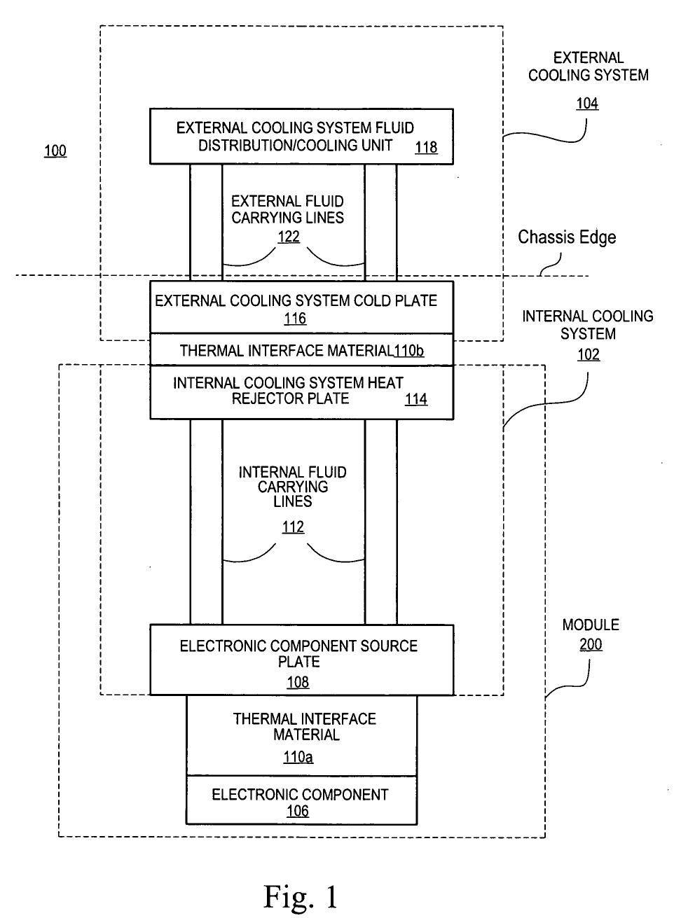

With reference to FIG. 1, there is shown a system 100 for cooling electronic components in accordance with an embodiment of the present invention. In the system 100 of FIG. 1, the internal fluid cooling system 102 and external fluid cooling system 104 work together to cool the electronic component 106. The internal fluid cooling system 102 may reside on a module 200 or the like that holds the electronic component 106, as well as other components. The module 200 can be inserted and removed from a chassis (edge of chassis depicted in FIG. 1), such as a rack or other housing. The internal cooling system 102 can be removed from the chassis to allow servicing of the electronic component 106 without disconnecting any fluid carrying line in the system 100.

The internal cooling system 102 has an electronic component source plate 108 that is thermally coupled to the electronic component 106 to draw heat away from the electronic component 106. The thermal interface layer 110a is a material that improves heat exchange by substantially eliminating air gaps that might otherwise occur between the source plate 108 and the electronic component 106. The air gaps might otherwise occur due to irregularities in the surfaces of the source plate 108 and/or the electronic component 106. As examples, the thermal interface layer 110a may be a thermally conductive grease, thermally conductive elastomer, thermally conductive tape, or other thermally conductive material.

The fluid carrying lines 112 are coupled between the source plate 108 and the internal cooling system heat rejector plate 114 in order to transfer heat from the source plate 108 to the heat rejector plate 114. The fluid carrying lines 112 may carry any type of fluid. Heat is transferred to the fluid when it is thermally coupled with the source plate 108. The heated fluid flows to the heat rejector plate 114 where heat is exchanged from the fluid to the heat rejector plate 114. The cooled fluid then returns to the source plate 108. The fluid carrying lines 112 are part of an active liquid cooling loop, in accordance with one embodiment. The fluid carrying lines 112 are part of a passive phase change loop, in accordance with another embodiment. Example embodiments of these loops are discussed herein.

The external cooling system 104 has a loop comprising a fluid distribution unit 118, external fluid carrying lines 122, and an external cooling system cold plate 116, in this embodiment. The external fluid carrying lines 122 may carry any type of fluid. The fluid distribution/cooling unit 118 comprises a refrigeration unit, in one embodiment. The fluid distribution/cooling unit 118 provides cooling fluid to the cold plate 116 via the external fluid carrying lines 122. When the fluid is thermally coupled with the cold plate 116, heat is transferred from the cold plate 116 to the fluid. The fluid then returns to the distribution/cooling unit 118 to remove heat from the fluid. Therefore, heat is removed from the cold plate 116.

In accordance to another embodiment, the fluid distribution/cooling unit 118 includes a refrigeration unit. In accordance to an alternative embodiment, the external cooling system 104 does not comprise a complete loop. For example, the external cooling system 104 may input cold water from ordinary water lines in the building, deliver the water to the cold plate 116 via the fluid lines 122, and dump the heated water.

The two cooling systems 102, 104 are thermally coupled to each other. In particular, the heat rejector plate 114 is thermally coupled to the cold plate 116. A thermal interface material 110b improves heat exchange by substantially eliminating air gaps. However, the heat rejector plate 114 and cold plate 116 form a separable heat exchange unit. Thus, the two cooling systems 102, 104 can be separated without disconnecting any of the fluid carrying lines 112, 122 in the system 100. This in turn means that the internal cooling system 102 can be removed from the chassis to service electronic components without disconnecting any of the fluid carrying lines 112, 122. The electronic components that are serviced may be the electronic component 106 that is cooled by the internal cooling system 102 or other components that are not cooled by the internal cooling system 102.

### Module Having Cooling System

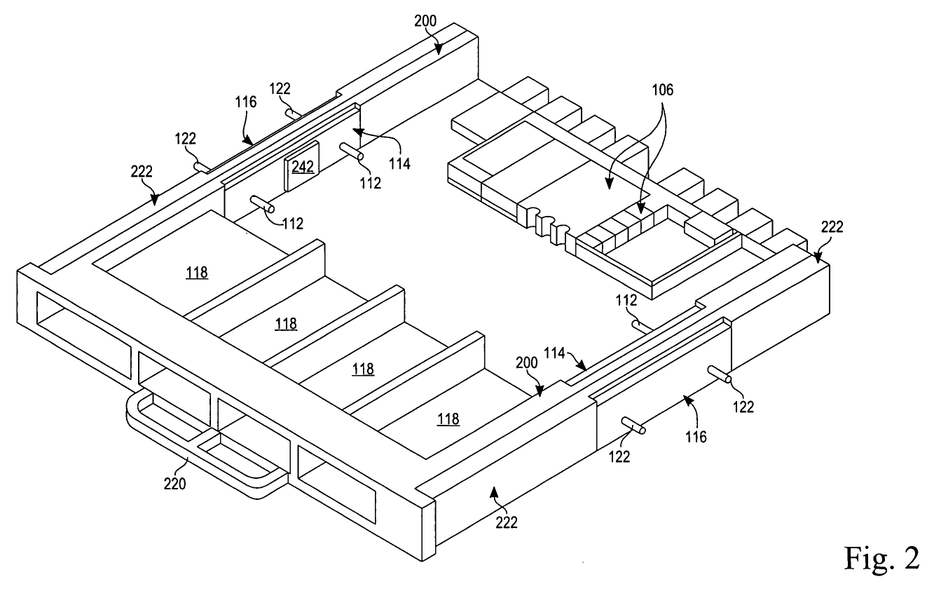

FIG. 2 shows a module 200, including electronic components, that can be removed from a chassis without disconnecting any cooling fluid carrying lines, in accordance with an embodiment of the present invention. FIG. 2 depicts a portion of the chassis 222 that extends along two sides of the module 200. The whole chassis may be a rack that houses many such modules 200. The module 200 can be slid into and removed from the chassis 222.

The module 200 has an internal cooling system. So as to not obscure the drawing, only a portion of the internal cooling system is depicted in FIG. 2. In particular, a pump 332, two heat rejector plates 114, and portions of fluid carrying lines 112 are depicted. The pump 332 pumps a cooling fluid through fluid carrying lines 112 such that the fluid is thermally coupled to the electronic components 106 and carries heat from the electronic components 106 to the heat rejecter plates 114.

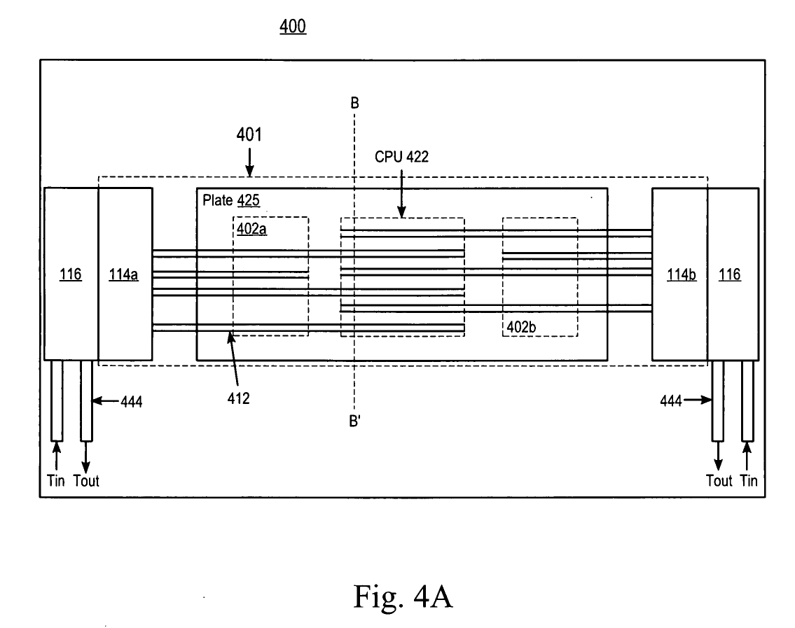

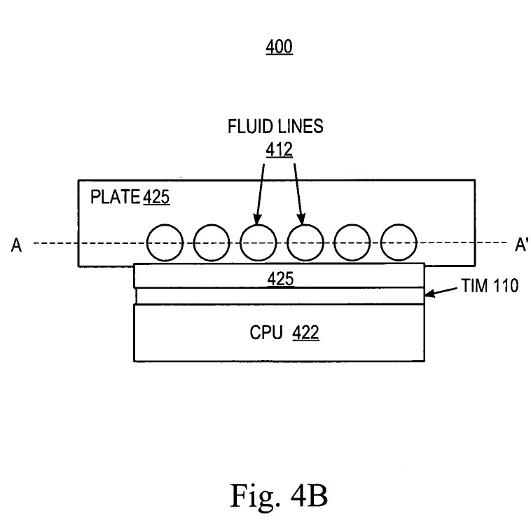

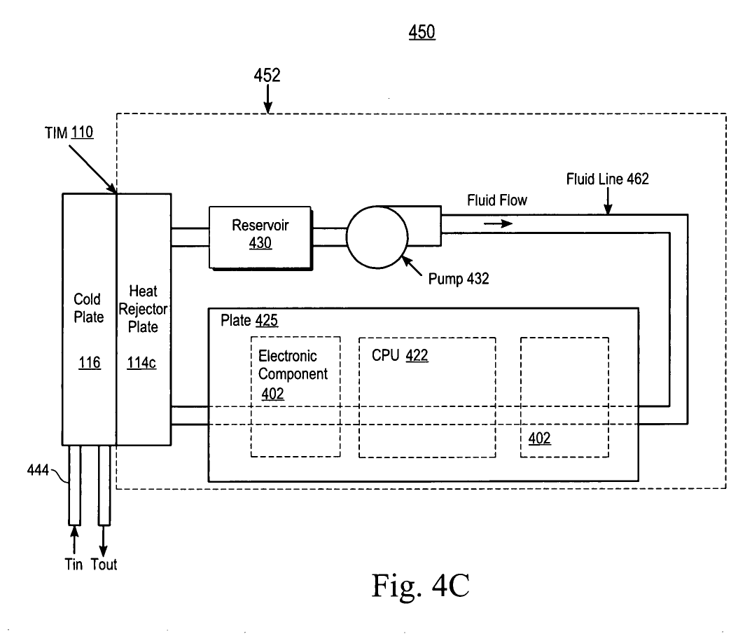

Thus, the module 200 in FIG. 2 has an active liquid cooling loop in that a pump is used. FIG. 4C depicts an example of a cooling system having an active liquid cooling loop, in accordance with an embodiment of the present invention. In another embodiment, the module 200 has a passive phase change loop cooling system. FIG. 4A and FIG. 4B depict an example of a cooling system having a passive phase change cooling loop, in accordance with an embodiment of the present invention. Furthermore, module 200 may be used with any other cooling system that allows the module 200 to be removed from a chassis 222 without disconnecting any fluid carrying lines.

The heat rejector plates 114 are thermally coupled with cold plates 116 that are attached to the chassis 222. The cold plates 116 are part of an external cooling system (not fully depicted in FIG. 2). Thus, the thermal coupling allows heat from the internal cooling system to be efficiently transferred to the external cooling system.

The module 200 has an injector/ejector handle 220 that is used to help remove and replace the module 200 from the chassis 222. The module 200 has a mechanism that facilitates forcing each heat rejector plate 114 to be thermally coupled with its respective cold plate 116, in accordance with an embodiment of the present invention. In one embodiment, the handle 220 is mechanically coupled to a plate coupler 242 to control the position of the heat rejector plate 114. In particular, the position of the heat rejector plate 114 is set to a first position such that when inserting the module 200 into the chassis 222 the module 200 moves freely. After the module 200 is inserted into the chassis 222, the handle 220 is adjusted to cause the plate coupler 242 to force the heat rejector plate 114 and the cold plate to be thermally coupled. For example, when first slid into the chassis 222, there may be a small air gap between the heat rejector plate 114 and the cold plate 116. The plate coupler 242, in response to movement of the handle 220, forces the heat rejector plate 114 to have physical contact with the cold plate 116, and therefore, to cause an efficient thermal coupling to be formed.

The internal cooling system can be physically attached to the module 200 by, for example, a fastener. Attaching the internal cooling system to the module 200 allows a good thermal coupling between the internal cooling system and the electronic components that are cooled by the cooling system. When removing the module 200 from the chassis 222, the internal cooling system is removed from the chassis 222 with the internal cooling system still attached to the components that it cools. However, if desired, once the module 200 has been removed from the chassis 222, the internal cooling system can be physically separated from the components that it cools without disconnecting any fluid carrying lines by unfastening the internal cooling system from the module 200. The module 200 also has electronic components 118 that are not cooled by the internal cooling system.

### Servicing Electronic Components

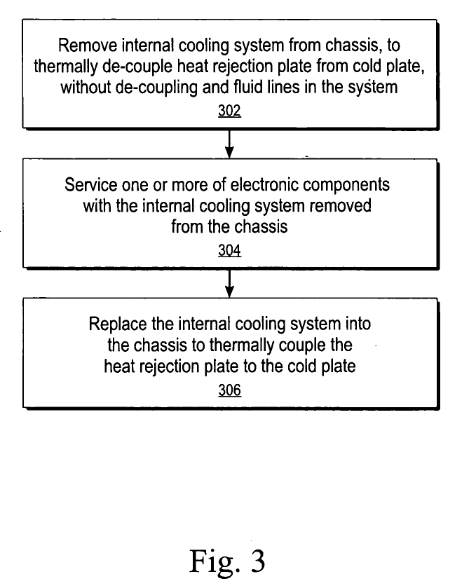

FIG. 3 shows steps of a process 300 for servicing electronic components that are housed in a chassis comprising a removable internal cooling system for cooling electronic components, in accordance with one embodiment of the present invention. The system 100 of FIG. 1 and the example module 200 of FIG. 2 are used to facilitate explanation or process 300. However, process 300 is not limited to the embodiment of FIG. 1 or the embodiment of FIG. 2.

In step 302, the internal cooling system 102 is removed from the chassis, to thermally de-coupling the heat rejector plate 114 from the cold plate 116, without de-coupling any of the fluid lines (112, 122) in the system 100. That is, none of the external fluid lines 122 and none of the internal fluid lines 112 need to be disconnected to service electronic components. As an example, removing the internal cooling system 102 is achieved by removing the module 200 that has the internal cooling system residing thereon.

In step 304, one or more electronic components on the module 200 are serviced with the internal fluid cooling system 102 removed from the chassis. The electronic components may be components on the module 200 other than those that are cooled by the internal cooling system. However, the electronic components that are cooled may also be serviced. In this case, the internal cooling system may be un-fastened from the module 200 to allow servicing of the electronic components.

In step 306, the internal fluid cooling system 102 is placed back into the chassis, to thermally couple the heat rejector plate 114 to the cold plate 116. For example, the module 200 is slid back into the chassis and a mechanism is used to cause the heat rejector plate 114 and the cold plate 116 to be thermally coupled. Therefore, electronic components can be serviced without disconnecting any fluid lines 112, 122.

### Passive Phase Change Loop Embodiment

FIG. 4A and FIG. 4B illustrate a system 400 with an internal cooling system having a passive phase change loop for cooling electronic components, in accordance with an embodiment of the present invention. FIG. 4A is a cross-sectional perspective of the system 400 taken along line A-A′ of FIG. 4B. FIG. 4B is a cross-sectional perspective of the system 400, taken along line B-B′ of FIG. 4A. Region 401 depicts an internal cooling system and electronic components. The internal cooling system in this embodiment has two heat rejector plates 114a, 114b, although more or fewer can be used. Three fluid lines 412 extend from the CPU 422 to each heat rejector plate 114a, 114b to cool the CPU 422. More or fewer fluid lines 412 could be used. A fluid line 412 extends from electronic component 402a to heat rejector plate 114a to cool electronic component 402a. A fluid line 412 extends from electronic component 402b to heat rejector plate 114b.

The heat rejector plates 114a, 114b are thermally coupled with each respective cold plate 116 to cool the electronic components. The cold plates 116 are coupled to a chassis (not depicted in FIG. 4A or FIG. 4B) and are part of an external cooling system. The cold plates 116 intake a fluid at a temperature (Tin) from one of the fluid carrying lines 444. After the fluid is thermally coupled with the cold plate 116, the fluid exits the cold plate 116 on another of the fluid carrying lines 444 at a temperature (Tout). The fluid in the external cooling system will typically be a liquid when entering the cold plate 116 and may be a liquid or vapor upon leaving the cold plate 116. Accordingly, the temperature of Tout could be equal or greater than the temperature of Tin.

The heat rejector plates 114 and the cold plates 116 form a separable heat exchange unit. Therefore, the internal cooling system can be removed from the chassis (not depicted in FIG. 4A, 4B) without disconnecting any fluid lines in either the internal cooling system or the external cooling system.

The fluid lines 412 are heat pipes, in one embodiment. Heat pipes are hollow cylinders filled with a fluid that vaporizes when the fluid is thermally coupled with the electronic component (e.g., CPU or other component), providing the electronic component is sufficiently hot. The fluid in the vapor phase flows to one of the heat rejector plates 114, where the fluid returns to the liquid phase due to transferring heat to the heat rejector plate 114. The cooled fluid then flows back to the end of the heat pipe that is thermally coupled with source plate 425. Thus, the heat pipes provide a phase change loop for the fluid. Further, the fluid in the heat pipes is able to exchange a great deal of heat even if there is a small temperature difference between the source plate 425 and the heat rejector plate 114. The fluid lines 412 are thermosyphon, in accordance with another embodiment. Similar to heat pipes, thermosyphon is a cooling technology with no moving parts within pipes. However, thermosyphon operates with a different principle than heat pipes. Heat pipes operation is based on capillary force, whereas thermosyphon operation is based on gravity force only.

The fluid lines 412 are embedded in the source plate 425, which may be formed of a material with a high heat conductivity. For example, the source plate 425 may be copper; however, other materials may be used. FIG. 4B depicts how the fluid lines 412 that cool the CPU 422 may be embedded in the source plate 425. The source plate 425 is thermally coupled with the CPU 422 via the thermal interface material (TIM) 110. The fluid lines 412 that cool the other electronic components 402 of FIG. 4A are not depicted in FIG. 4B.

While FIG. 4C depicts a single source plate 425, there may be any number of source plates 425. For example, a separate source plate 425 could be thermally coupled to each of the electronic components 402, 422.

### Active Liquid Cooling Loop Embodiment

FIG. 4C shows a top perspective view of system 450 having an internal cooling system with an active liquid cooling loop, in accordance with one embodiment of the present invention. Region 452 depicts the active liquid cooling loop and various electronic components 402, 422 that are cooled thereby. The active liquid cooling loop includes a reservoir 430, a pump 432, a fluid line 462, and a heat rejector plate 114c. The fluid carried in the fluid line 462 is typically a liquid, in this embodiment. However, the fluid may vaporize.

The fluid line 462 is embedded in the source plate 425, which is a material with high heat conductivity. The source plate 425 is thermally coupled to the various electronic components (e.g., components 402, CPU 422). For example, the source plate 425 may be thermally coupled to the electronic components 402, 422. While FIG. 4C depicts a single source plate 425, there may be any number of source plates 425. For example, a separate source plate 425 could be thermally coupled to each of the electronic components 402, 422.

Referring again to FIG. 4C, the pump 432 causes the liquid in the fluid line 462 to circulate such that the liquid is heated as it passes through the source plate 425 to the heat rejector plate 114c. After transferring heat to the heat rejector plate 114c, the fluid flows to the reservoir 430. The internal cooling system 452 can have any number of fluid lines 462 to present a greater surface area for thermal coupling with the source plate 425. Also, the fluid line 462 may have a different shape than depicted in FIG. 4C to present a greater surface area for thermal coupling with the source plate 425.

The heat rejector plate 114c and the cold plate 116 form a separable heat exchange unit, such that the internal cooling system 401 can be removed from the chassis (not depicted in FIG. 4C) without disconnecting any fluid lines in the system 450. For example, the fluid lines 462 in the active cooling line are not disconnected. Moreover, the external fluid lines 444 are not disconnected. Therefore, the electronic components can be serviced without disconnecting any fluid lines. The TIM 110 is a thermal interface layer similar to previously described TIMs. The system 450 can have any number of heat rejector plates 114c.

At this point, it should be noted that although the invention has been described with reference to specific embodiments, it should not be construed to be so limited. Various modifications may be made by those of ordinary skill in the art with the benefit of this disclosure without departing from the spirit of the invention. Thus, the invention should not be limited by the specific embodiments used to illustrate it but only by the scope of the claims and the equivalents thereof.

What is claimed is:

1. A system for cooling electronic components of a module, said system comprising:
a first cooling system comprising a cold plate coupled to a chassis that houses the module, wherein the cold plate is coupled to a first line that carries a first fluid; and
a second cooling system operable to cool at least one of the electronic components of the module, wherein the second cooling system comprises a heat rejecter plate and a second line that carries a second fluid, wherein the heat rejecter plate is coupled to the second line, and wherein the second line is thermally coupled to the at least one of the electronic components, and wherein the heat rejecter plate is thermally coupled to the cold plate to transfer heat from the second cooling system to the first cooling system;
wherein the second cooling system may be removed from the chassis, thereby thermally de-coupling the heat rejecter plate from the cold plate, without de-coupling the first line from the cold plate and without de-coupling the second line from the heat rejecter plate.

2. The system of claim 1, wherein the second cooling system comprises an active liquid cooling loop.

3. The system of claim 1, wherein the second cooling system comprises a passive phase change loop.

4. The system of claim 3, wherein the passive phase change loop comprises one or more heat pipes.

5. The system of claim 1, further comprising a thermal interface material between the heat rejecter plate and the cold plate.

6. The system of claim 1, wherein the module comprises at least one serviceable component that is not cooled by the second cooling system.

7. The system of claim 1, wherein the second line may be separated from the electronic components without de-coupling the first line from the cold plate and without de-coupling the second line from the heat rejecter plate.

8. The system of claim 1, wherein the chassis is configured to receive a plurality of modules.

9. A method of servicing electronic components of a module that is housed in a chassis, wherein a cold plate of a first cooling system is coupled to the chassis, and wherein the cold plate is coupled to a first line that carries a first fluid, and wherein the module comprises a second cooling system for cooling at least one of the electronic components of the module, wherein the second cooling system comprises a heat rejecter plate and a second line that carries a second fluid, wherein the second line is thermally coupled to at least one of the electronic components, wherein the heat rejecter plate is coupled to the second line, and wherein the cold plate is thermally coupled to the heat rejecter plate to transfer heat from the second cooling system to the first cooling system, wherein said method comprises:
removing the second cooling system from the chassis, to thermally de-couple the heat rejection plate from the cold plate, without de-coupling the first line from the cold plate and without de-coupling the second line from the heat rejection plate;
servicing one or more of the electronic components of the module with the second cooling system removed from the chassis; and
replacing the second cooling system into the chassis to thermally couple the heat rejection plate to the cold plate.

10. The method of claim 9, wherein servicing one or more of the electronic components comprises servicing electronic components that are cooled by the second cooling system.

11. The method of claim 9, further comprising separating the second cooling system from the electronic components that are cooled by the second cooling system, without de-coupling the first line from the cold plate and without de-coupling the second line from the heat rejection plate.

12. The method of claim 9, wherein servicing one or more of the electronic components comprises servicing electronic components on the module that are not cooled by the second cooling system.

13. The method of claim 9, wherein removing the second cooling system from the chassis comprises removing an active liquid cooling loop from the chassis.

14. The method of claim 9, wherein removing the second cooling system from the chassis comprises removing a passive phase change loop from the chassis.

15. The method of claim 9, wherein removing the passive phase change loop from the chassis comprises removing at least one heat pipe from the chassis.

16. A module housing electronic components, said module comprising:
a cooling system operable to cool at least one of the electronic components of the module, wherein the cooling system comprises a heat rejecter plate and a line that carries a fluid, wherein the line is thermally coupled to at least one of the electronic components, and wherein the heat rejecter plate is coupled to the line; and
a mechanism having a first position that allows the module to be freely moved within a chassis to insert and remove the module from the chassis and a second position that causes the heat rejecter plate to be thermally coupled to a cold plate coupled to the chassis to transfer heat from the cooling system to an external cooling system that comprises the cold plate;
wherein the first position thermally de-couples the heat rejecter plate from the cold plate, without disconnecting the line from the heat rejecter plate.

17. The module of claim 16, wherein the cooling system comprises an active liquid cooling loop.

18. The module of claim 16, wherein the cooling system comprises a passive phase change loop.

19. The module of claim 16, wherein the fluid changes states to provide heat transfer.

20. The module of claim 16, wherein the mechanism includes a plate coupler that operates to thermally couple the heat rejecter plate with the cold plate.
